(19) United States
(12) Patent Application Publication
(10) Pub. No.: US 2026/0089896 A1
(43) Pub. Date: Mar. 26, 2026

(54) COOLER

(71) Applicant: FUJI ELECTRIC CO., LTD., Kawasaki-shi (JP)

(72) Inventors: Akira KAMIYA, Tokyo (JP); Takumi SATO, Tokyo (JP); Daiki SANO, Matsumoto-city (JP)

(73) Assignee: FUJI ELECTRIC CO., LTD., Kawasaki-shi, Kanagawa (JP)

(21) Appl. No.: 19/310,513

(22) Filed: Aug. 26, 2025

(30) Foreign Application Priority Data
Sep. 24, 2024 (JP) 2024-165263
Feb. 14, 2025 (JP) 2025-022599

(51) Int. Cl. H05K 7/20

(52) U.S. Cl. CPC H05K 7/20927

(57) ABSTRACT

A cooler includes a case including: an inlet for a refrigerant; an outlet for the refrigerant; a first member with a first surface that absorbs heat from a cooled body and a second surface opposite to the first surface; a second member with a third surface facing the second surface; protrusions that extend from the third surface toward the second surface; and at least one baffle that is disposed for at least one protrusion from among the protrusions and extends from the third surface toward the second surface. The at least one baffle has a protruding height that is less than a protruding height of the at least one protrusion. The at least one baffle is spaced apart from the at least one protrusion and is disposed on a side opposite the inlet relative to the at least one protrusion.

### CROSS REFERENCES TO RELATED APPLICATION

This Application claims priority from Japanese Patent Application No. 2024-165263, filed Sep. 24, 2024, and Japanese Patent Application No. 2025-022599, filed Feb. 14, 2025, the entire content of each of which is incorporated herein by reference.

### BACKGROUND

### Technical Field

This disclosure relates to coolers.

### Description of Related Art

A known semiconductor device, such as a power converter, converts DC power into AC power. Such a semiconductor device has a cooler that dissipates heat from a heat generating element.

A cooler, described in WO 2014/069174 A1, includes a substrate for heat dissipation joined to an insulating substrate with a semiconductor element, fins opposing to the insulating substrate, and a box-shaped cooling case for the fins. The cooling case has an inlet and an outlet for a refrigerant, and the refrigerant flows into the cooling case. These fins are arranged at a predetermined pitch at specific intervals. The arrangement of the fins increases the heat dissipation area, resulting in efficient heat exchange.

### SUMMARY

The flow of refrigerant decreases after each protrusion inside the cooler. This creates regions of restricted movement of the refrigerant, which reduce heat dissipation efficiency and may ultimately impair cooling performance.

In order to solve the aforementioned problems, a cooler, according to this disclosure, includes a case including: an inlet for a refrigerant; an outlet for the refrigerant; a first member with a first surface that absorbs heat from a cooled body and a second surface opposite to the first surface; a second member with a third surface facing the second surface; a plurality of protrusions that extends from the third surface toward the second surface; and at least one baffle that is disposed for at least one protrusion from among the plurality of protrusions and extends from the third surface toward the second surface. The at least one baffle has a protruding height that is less than a protruding height of the at least one protrusion. The at least one baffle is spaced apart from the at least one protrusion and is disposed on a side opposite the inlet relative to the at least one protrusion.

### BRIEF DESCRIPTION OF DRAWINGS

FIG. 1 is a perspective view of a cooler according to a first embodiment.

FIG. 2 is a perspective view of a second member of the cooler illustrated in FIG. 1.

FIG. 3 includes a top view, a front view, side views, and a cross-sectional view of the second member shown in FIG. 2.

FIG. 4 is a plan view of protrusions and baffles illustrated in FIG. 2.

FIG. 5 is a cross-sectional view of the protrusions and the baffles illustrated in FIG. 4.

FIG. 6 illustrates a flow of refrigerant in a comparative example.

FIG. 7 illustrates a flow of refrigerant in this embodiment.

FIG. 8 illustrates the magnitude of the flow velocity of the refrigerant in the comparative example.

FIG. 9 illustrates the magnitude of the flow velocity of the refrigerant in this embodiment.

FIG. 10 illustrates thermal resistances in both this embodiment and the comparative example.

FIG. 11 illustrates the protrusions and the baffles shown in FIG. 4.

FIG. 12 illustrates baffles and protrusions according to a first modification.

FIG. 13 is a plan view of baffles according to a second modification.

FIG. 14 is a plan view of baffles according to a third modification.

FIG. 15 is a plan view of baffles according to a fourth modification.

FIG. 16 is a plan view of baffles according to a fifth modification.

FIG. 17 illustrates protrusions and baffles according to a sixth modification.

FIG. 18 is a cross-sectional view of a baffle according to a seventh modification.

FIG. 19 is a cross-sectional view of a baffle according to an eighth modification.

FIG. 20 is a cross-sectional view of a baffle according to a ninth modification.

FIG. 21 illustrates a portion of a second member according to a tenth modification.

FIG. 22 is a cross-sectional view taken along line α-α of FIG. 21.

FIG. 23 is a cross-sectional view of a portion of a second member according to an eleventh modification.

FIG. 24 is a cross-sectional view of a portion of a second member according to a twelfth modification.

FIG. 25 is a cross-sectional view of a portion of a second member according to a thirteenth modification.

FIG. 26 illustrates a portion of a second member according to a fourteenth modification.

FIG. 27 is a cross-sectional view taken along line α-α of FIG. 26.

FIG. 28 illustrates a portion of a second member according to a fifteenth modification.

FIG. 29 is a cross-sectional view taken along line α-α of FIG. 28.

FIG. 30 illustrates a portion of a second member according to a sixteenth modification.

FIG. 31 is a cross-sectional view taken along line α-α of FIG. 30.

FIG. 32 is a cross-sectional view of a portion of a second member according to a seventeenth modification.

FIG. 33 is a cross-sectional view of a portion of a second member according to an eighteenth modification.

FIG. 34 illustrates a portion of a second member according to a nineteenth modification.

FIG. 35 is a cross-sectional view taken along line segment A2 of FIG. 26.

FIG. 36 is a cross-sectional view of a portion of a second member according to a twentieth modification.

FIG. 37 is a cross-sectional view of a portion of a second member according to a twenty-first modification.

FIG. 38 is a cross-sectional view taken along line β-β of FIG. 37.

FIG. 39 illustrates a portion of a second member according to a twenty-second modification.

FIG. 40 is a cross-sectional view taken along line γ-γ of FIG. 39.

FIG. 41 is a cross-sectional view taken along line segment A2 of FIG. 39.

### DESCRIPTION OF EMBODIMENTS

Embodiments according to this disclosure will be described below with reference to the accompanying drawings. In the drawings, dimensions and scales of parts are appropriately different from actual ones, and some of the parts are schematically illustrated for clarity. The scope of this disclosure is not limited to these forms unless otherwise specified in the following description to the effect that this disclosure is limited thereto. In this specification, the term “equal” not only means substantially equal, but also includes a difference due to a manufacturing error.

### 1. Embodiment

### 1-1. Overview of Cooler 100

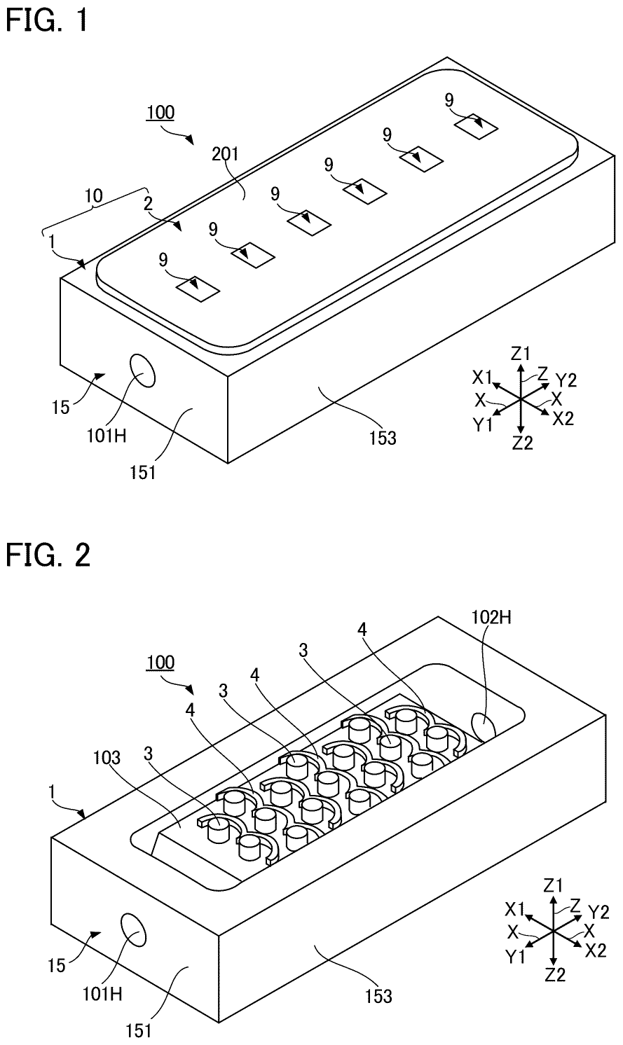

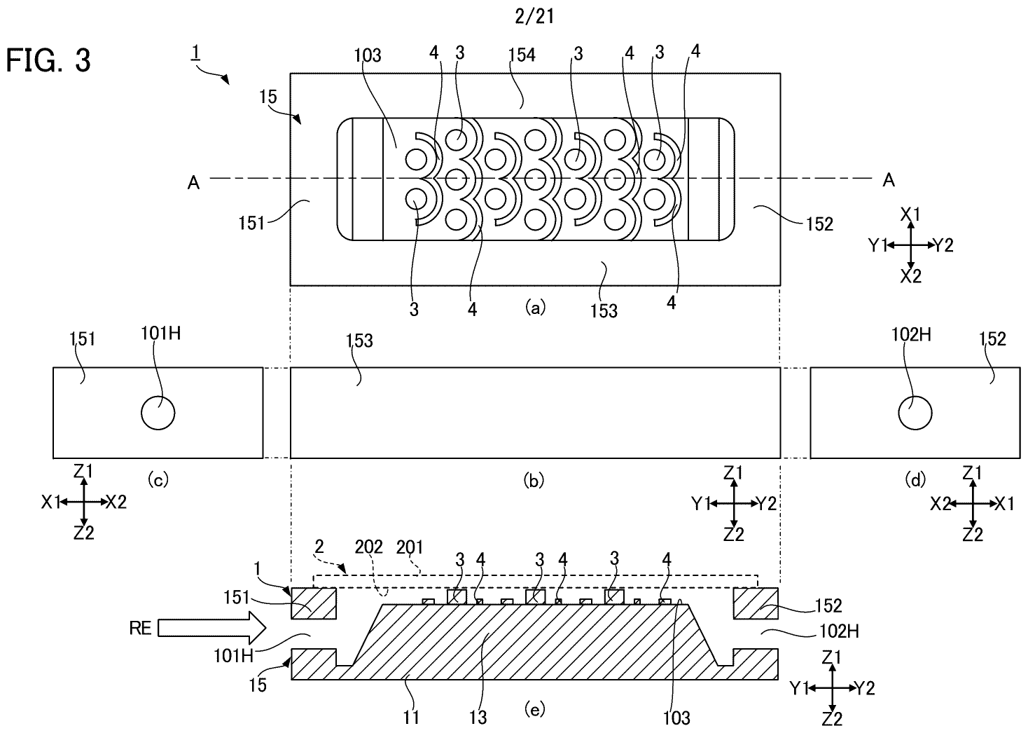

FIG. 1 is a perspective view of a cooler 100 according to a first embodiment. FIG. 2 is a perspective view of a case of the cooler 100 illustrated in FIG. 1. FIG. 3 includes a top view (a), a front view (b), side views (c and d), and a cross-sectional view (e) of a second member 1 of FIG. 2.

The following description will be given while appropriately using an X axis, a Y axis, and a Z axis that intersect with each other. The “X1” represents the X axis in a positive direction, and the “X2” represents the X axis in a negative direction. The “Y1” represents the Y axis in a positive direction, and the “Y2” represents the Y axis in a negative direction. The “Z1” represents the Z axis in a positive direction, and the “Z2” represents the Z axis in a negative direction. A view in a direction along the Z axis is referred to as a “plan view.” The Z1 also corresponds to an upward direction, and the Z2 also corresponds to a downward direction.

The cooler 100 illustrated in FIG. 1 is used to cool power electronics products, such as inverters and rectifiers. These components may be mounted in railway vehicles, automobiles, or household electrical applications. The power electronic products may have power semiconductor elements, such as diodes, or insulated gate bipolar transistors (IGBTs). The power semiconductor elements are examples of cooled bodies 9, which are subjected to be cooled by the cooler 100. As heat generating element, the cooled bodies 9 are not limited to these power semiconductor elements. The cooled bodies 9 may be any other electric components that generate heat when driven or energized and requires cooling.

As illustrated in FIGS. 1 to 3, the cooler 100 includes a case 10, protrusions 3, and baffles 4.

1-1a. Case 10

The case 10 has an internal space that serves as a flow path for a refrigerant RE. The case 10 has an inlet 101H through which the refrigerant RE enters, and an outlet 102H through which the refrigerant RE exits. The refrigerant RE flows into the flow path from the inlet 101H and is discharged from the outlet 102H. As such, the refrigerant RE flows from the inlet 101H toward the outlet 102H.

The refrigerant RE is a medium in a liquid state at room temperature, and it may consist of water (e.g., pure water), or a mixture of water and alcohol. The alcohol may be ethanol or methanol. The type of the refrigerant RE may be a type other than the above-described types. A surfactant is preferably added to the refrigerant RE. The surfactant may be a nonionic surfactant, or an ionic surfactant, such as an anionic surfactant and a cationic surfactant. Specific examples of the surfactant include a fluorine-based surfactant, a silicone-based surfactant, and a hydrocarbon-based surfactant. When the refrigerant is water, it is preferable to use a hydrocarbon-based surfactant having excellent solubility.

The case 10 is made of a material with excellent thermal conductivity, such as copper, aluminum, and an alloy. The case 10 includes a first member 2 and a second member 1. The second member 1 is a box with an opening oriented in the Z1 direction. The first member 2 is a lid that covers the opening. The first member 2 and the second member 1 may be made of the same material or different materials.

As illustrated in FIG. 3, the second member 1 is flat. The first member 2 has a first surface 201 and a second surface 202. As illustrated in FIG. 1, more than two cooled bodies 9 are arranged on the first surface 201 and are cooled by the cooler. The first surface 201 absorbs heat from the cooled bodies 9. The first surface 201 and each cooled body 9 may be in direct contact with each other, or another member may be interposed between the first surface 201 and each cooled body 9. The second surface 202 is opposite to the first surface 201.

The second member 1 includes a bottom 11, a side wall 15, and a base 13. The bottom 11, the side wall 15, and the base 13 are unitarily formed; however, they may be individual elements that are bonded together. The bottom 11 is flat.

The side wall 15 extends in the Z1 direction from the bottom 11. The side wall 15 has a first side wall 151, a second side wall 152, a third side wall 153, and a fourth side wall 154. The first side wall 151 and the second side wall 152 face each other, and the third side wall 153 and the fourth side wall 154 face each other. The inlet 101H is located on the first side wall 151. The outlet 102H is located on in the second side wall 152. The inlet 101H is an opening penetrating through the first side wall 151, and the outlet 102H is an opening penetrating through the second side wall 152.

The base 13 is positioned relative to the bottom 11 in the Z1 direction and is thicker than the bottom 11 along the Z axis. In one example, the base 13 is trapezoidal in cross-section. The base 13 enhances the cooling performance of the cooler 100 as compared to that without the base. The base 13 has an upper surface corresponding to a third surface 103 facing the second surface 202.

1-1b. Protrusions 3 and Baffles 4

As illustrated in FIGS. 2 and 3, the protrusions 3 are spaced apart and arranged within the internal space of the case 10. Each protrusion 3 is a columnar protrusion connected to the third surface 103 and extends toward the second surface 202. Each protrusion 3 does not contact the first member 1; however, each may be in contact with the first member 2. In this example, the protrusions 3 are cylindrical; however, they are not limited thereto. Examples of the shape of each protrusion 3 include: a prism shape (e.g., triangular prism), a pyramid shape (e.g., triangular pyramid), a tapered shape (e.g., cone), a hemispherical shape (e.g., dome), and a combination of these.

The arranged protrusions 3 increase a flow velocity of the refrigerant RE in contact with the second surface 202 of the first member 2, which enhances the cooling performance of the cooler 100.

As illustrated in FIGS. 2 and 3, the baffles 4 are located within the internal space of the case 10. Each baffle 4 is a columnar protrusion connected to the third surface 103 and extends toward the second surface 202. The baffles 4 are arranged for the respective protrusions 3. In this embodiment, the wall-shaped baffles 4 correspond one-to-one to the protrusions 3. The baffles 4 are spaced apart from the protrusions 3.

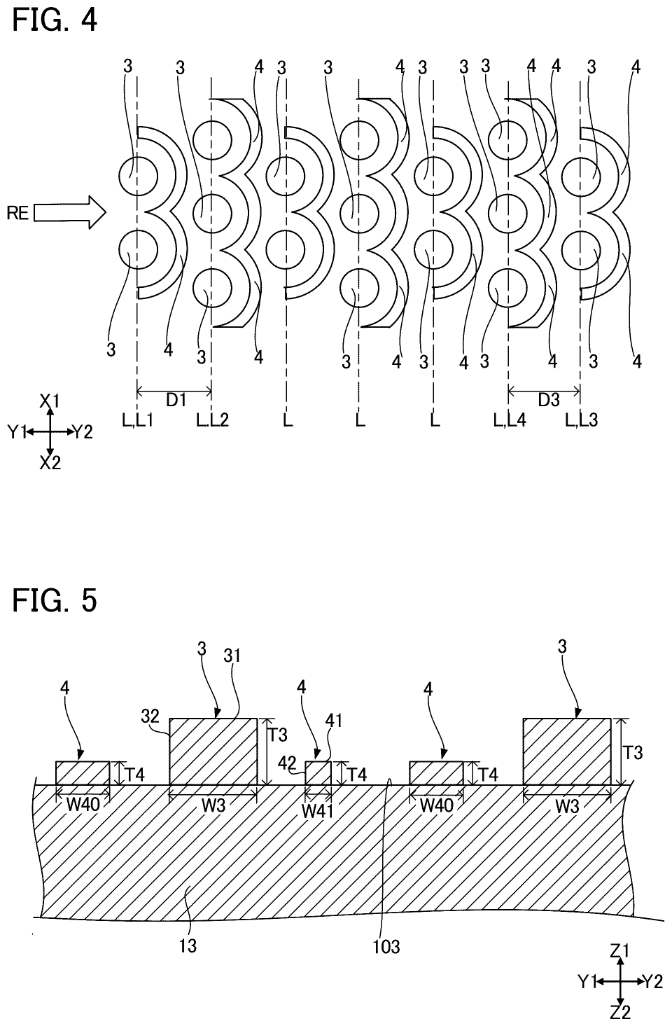

FIG. 4 is a plan view of the protrusions 3 and the baffles 4 illustrated in FIG. 2. As illustrated in FIG. 4, the protrusions 3 are arranged in a staggered pattern in plan view. The protrusions 3 are grouped into two or more protrusion rows L, which are arranged at intervals along the Y2 direction. The Y2 direction corresponds to the direction of flow of the refrigerant RE. In this example, the protrusions 3 are grouped into seven protrusion rows L. Each protrusion row L is a set of protrusions 3 linearly arranged along the X axis. In this embodiment, these protrusion rows L are arranged at equal intervals.

From among these protrusion rows L, a protrusion row L closest to the inlet 101H is defined as a first protrusion row L1. A protrusion row L next closest to the inlet 101H after the first protrusion row L1 is defined as a second protrusion row L2. A protrusion row L closest to the outlet 102H is defined as a third protrusion row L3. A protrusion row L next closest to the outlet 102H after the third protrusion row L3 is defined as a fourth protrusion row L4. A distance D1 between the first protrusion row L1 and the second protrusion row L2 is equal to a distance D3 between the third protrusion row L3 and the fourth protrusion row L4.

When viewed from the Y2 direction (i.e., a direction of flow of the refrigerant RE), the center of each protrusion 3 in a certain protrusion row L does not overlap with the center of each protrusion 3 located within an adjacent protrusion row L. The arrangement of the protrusions 3 facilitates a smooth flow of the refrigerant RE over the entire internal space.

As described above, the baffles 4 correspond one-to-one to the protrusions 3. Each baffle 4 is disposed close to the outlet 102H of the corresponding protrusion 3. In this embodiment, each baffle 4 has an arc shape in plan view. Furthermore, baffles 4, corresponding to protrusions 3 located within the same protrusion row L, are connected to each other.

FIG. 5 is a cross-sectional view of the protrusions 3 and the baffles 4 illustrated in FIG. 4. As illustrated in FIG. 5, each protrusion 3 has a protruding height T3 along the Z axis (the direction of Z1) that is greater than a protruding height T4 of each baffle 4 along the Z axis. Furthermore, each protrusion 3 has a width W3 along the Y axis (the direction of flow of the refrigerant RE) that is greater than a width W41 of each baffle 4 along the Y direction. Here, the width W3 is greater than a width W40 along the Y axis at a connection portion between two adjacent baffles 4.

Each protrusion 3 has a top surface 31 and a side surface 32. The top surface 31 is a portion of the protrusion 3 closest to the second surface 202. In this embodiment, the top surface 31 is parallel to the third surface 103 and is orthogonal to the Z axis. The top surface 31 is circular in plan view. The side surface 32 is cylindrical and connects the top surface 31 to the third surface 103. In this embodiment, the side surface 32 is parallel to the Z axis.

Each baffle 4 has a top surface 41 and a side surface 42. The top surface 41 is a portion of the baffle 4 closest to the second surface 202. In this embodiment, the top surface 41 is parallel to the third surface 103 and is orthogonal to the Z axis. The top surface 41 is circular in plan view. The side surface 42 is cylindrical and connects the top surface 41 to the third surface 103. In this embodiment, the side surface 42 is parallel to the Z axis.

As described above, each protrusion 3 has the protruding height T3 along the Z axis (the direction of Z1) that is greater than the protruding height T4 of each baffle 4 along the Z axis. The baffle 4 is spaced apart from the corresponding protrusion 3 and is disposed on a side opposite the inlet 101H relative to this protrusion 3. Such a baffle 4 serves to prevent a deceleration of flow of the refrigerant RE in the downstream region of the protrusion 3 (the region toward the outlet 102H), thereby reducing the thermal resistance on the third surface 103 over the entire region. This reduction enhances the cooling performance of the cooler 100.

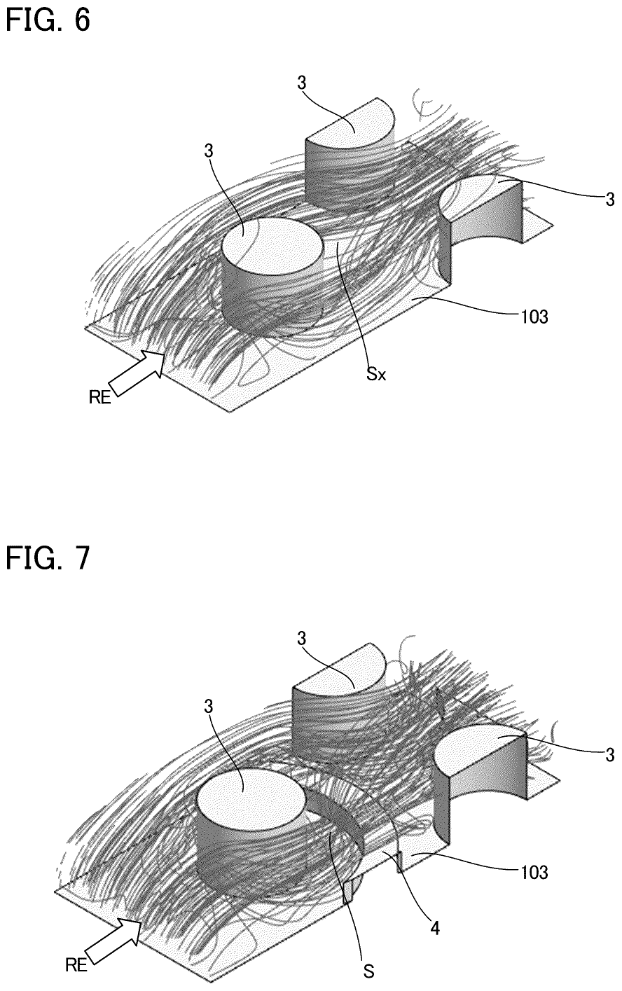

FIG. 6 illustrates a flow of refrigerant RE in a comparative example. FIG. 7 illustrates a flow of refrigerant RE in this embodiment. In the comparative example illustrated in FIG. 6, no baffle 4 is provided. Conversely, in this embodiment illustrated in FIG. 7, a baffle 4 is provided. Flow lines of the refrigerants RE are depicted in FIGS. 6 and 7.

In the comparative example of FIG. 6, the refrigerant RE exhibits minimal flow in a downstream region Sx of the protrusion 3 (the region toward the outlet 102H). Conversely, in this embodiment shown in FIG. 7, the refrigerant RE efficiently flows also in a downstream region S of the protrusion 3 (the region toward the outlet 102H), similar to its flow in the upstream region (the region toward the inlet 101H). This is because the refrigerant RE impacts the upstream region of the baffle 4 (the region toward the inlet 101H), which causes a change in directions of flow within the region S between protrusion 3 and baffle 4. As a result, the flow rate of the refrigerant RE passing through the region S increases in this embodiment, compared to the downstream the region Sx of the protrusion 3 (the region toward the outlet 102H).

As illustrated in FIGS. 6 and 7, each arranged baffle 4 serves to prevent a decrease in flow rate in the downstream region S of the protrusion 3 (the region toward the outlet 102H).

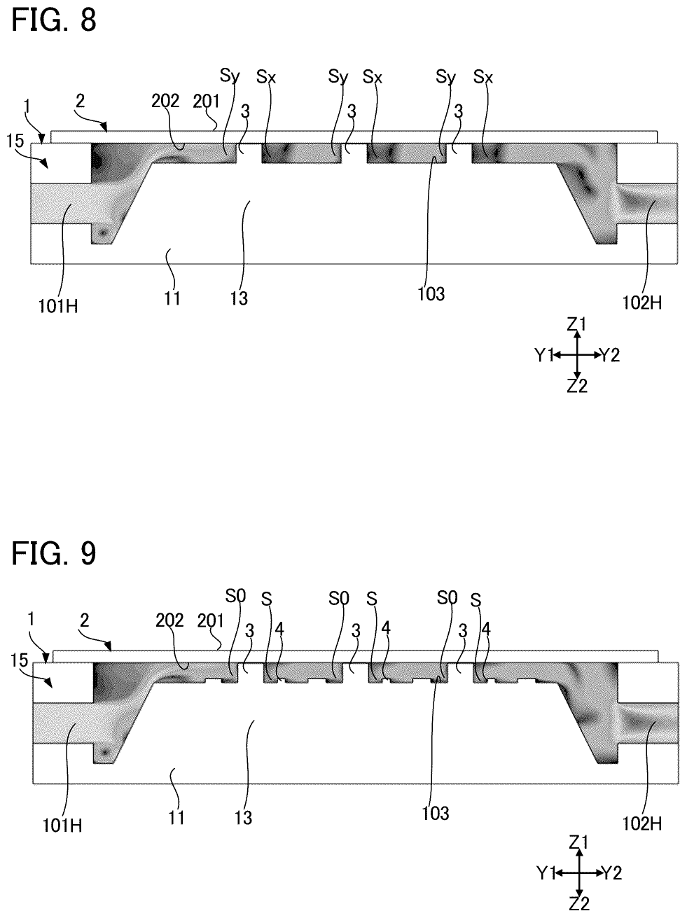

FIG. 8 illustrates the magnitude of the flow velocity of the refrigerant RE in the comparative example. FIG. 9 illustrates the magnitude of the flow velocity of the refrigerant RE in this embodiment. In the comparative example of FIG. 8, a brightness level of the downstream region Sx of the protrusion 3 (the region toward the outlet 102H) is less than that of an upstream region Sy of the protrusion 3 (the region toward the inlet 101H). This indicates that a flow velocity of the refrigerant RE in the region Sx is less than that of the refrigerant RE in the region Sy.

In this embodiment of FIG. 9, a brightness in the region S on the side close to the outlet 102H of the protrusion 3 is substantially equal to a brightness in a region S0 on the side close to the inlet 101H of the protrusion 3. This indicates that a flow velocity of the refrigerant RE in the region S is not inferior to that of the refrigerant RE in the region S0, but is substantially equal to the flow velocity of the refrigerant RE in the region S0.

As illustrated in FIGS. 8 and 9, each arranged baffle 4 serves to prevent a decrease in flow velocity in the downstream region S of the protrusion 3 (the region toward the outlet 102H).

The protruding height T4 of the baffle 4 is less than the protruding height T3 of the protrusion 3. If the protruding height T4 is equal to or greater than the protruding height T3, the flow rate and flow velocity of the refrigerant RE may decrease in the downstream region of the baffle 4 (the region toward the outlet 102H). Conversely, if the protruding height T4 is less than the protruding height T3, the decrease in flow rate and the flow velocity rarely occurs.

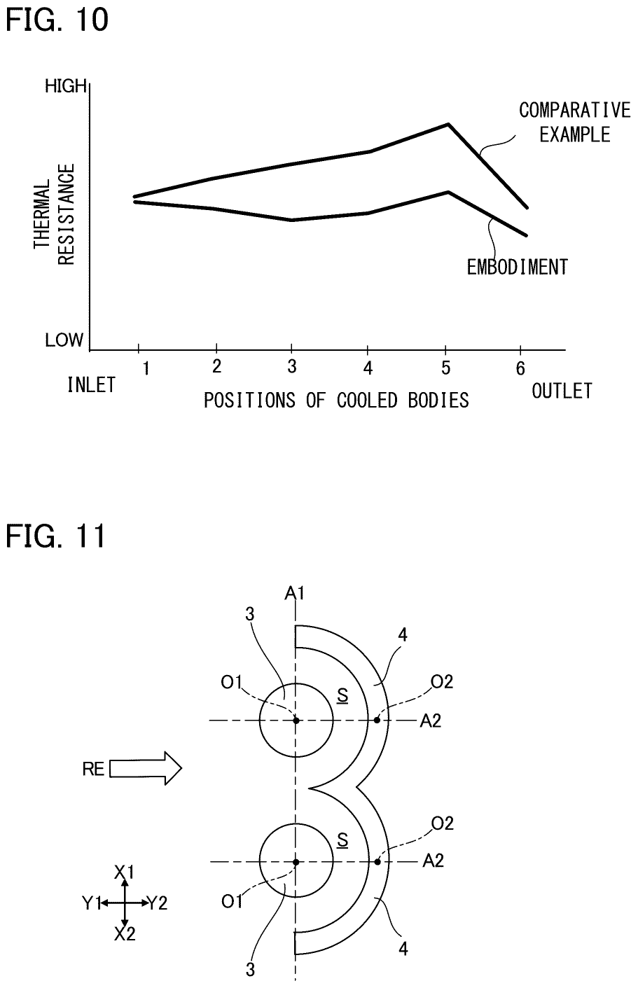

FIG. 10 illustrates thermal resistances in both this embodiment and the comparative example. In FIG. 10, the vertical axis represents thermal resistances of the cooled bodies 9, and the horizontal axis represents positions thereof. Specifically, six cooled bodies 9 are arranged on the first surface 201. A cooled body 9 closest to the inlet 101H is numbered “1,” and the remaining cooled bodies 9 are numbered “2,” “3,” “4,” “5,” and “6” sequentially toward the outlet 102H, starting from “1.” These six cooled bodies 9 are arranged in a straight line at substantially equal intervals from the inlet 101H toward the outlet 102H.

As illustrated in FIG. 10, according to the cooler 100 of this embodiment, the thermal resistances of each of the cooled bodies 9 is less than those in the comparative example, regardless of their positions on the first surface 201. As shown from FIG. 10, the baffles 4 enhance the cooling performance of the cooler 100.

FIG. 11 illustrates the protrusions 3 and the baffles 4 shown in FIG. 4. As illustrated in FIG. 11, a situation will be considered in which a virtual line A1 passes through the center O1 of the protrusion 3 in plan view along the X1 direction, which is perpendicular to the direction of flow of the refrigerant RE. In this situation, each baffle 4 is positioned closer to the outlet 102H than the virtual line A1 of the corresponding protrusion 3.

Thus, the baffle 4 effectively serves to prevent a decrease in flow velocity and flow rate of the refrigerant RE in the downstream region of the baffle 4 (the region toward the outlet 102H). It is noted that the baffle 4 may include a portion positioned closer to the inlet 101H than the virtual line A1. However, in this configuration, the flow rate and flow velocity of the refrigerant RE may decrease in the region S, as compared to when the baffle 4 does not include such a portion.

Baffles 4, corresponding to protrusions 3 located within the same protrusion row L, are connected to each other. That is, protrusions 3 include two or more protrusions 3 arranged to be spaced apart from each other in the X1 direction, which is orthogonal to the direction of flow of the refrigerant RE. Two or more baffles 4 corresponding to the two or more protrusions 3 are provided and are connected to each other.

Connecting the baffles 4 located within the same protrusion row L serves to prevent decreases in the flow velocity and flow rate of refrigerant RE in the region S, compared to when the baffles 4 are not connected.

Each protrusion 3 is circular in plan view. In addition, each baffle 4 has an arc shape that corresponds to the shape of the protrusion 3 in plan view. The arc-shaped baffles 4 increase the flow rate and flow velocity of the refrigerant RE in the region S without requiring an offset, as compared with straight baffles.

Each baffle 4 is concentric with the protrusion 3. Therefore, the distance between the baffle 4 and the protrusion 3 remains uniform across the entire region of the baffle 4. A line segment A2, extending through the center O1 of the protrusion 3 in the direction of flow of the refrigerant, also passes through the center O2 of the baffle 4. Each of the centers O1 and O2 is a geometric center in plan view.

Each baffle 4 concentric with the protrusion 3 increases the flow rate and flow velocity of the refrigerant RE in the region S without requiring an offset.

In this embodiment, the baffles 4 are arranged for all of the protrusions 3. That is, these baffles 4 correspond one-to-one to the protrusions 3. This arrangement prevents a decrease in flow velocity and flow rate of the refrigerant RE in the downstream region of all the protrusions 3 (the region toward the outlet 102H), which effectively improves the cooling performance of the cooler 100.

### 2. Modifications

This disclosure is not limited to the foregoing embodiment, and a variety of modifications can be derived as described below. These modifications can be appropriately combined as long as they do not conflict.

### 2-1. First Modification

FIG. 12 is a plan view of baffles 4 and protrusions 3 according to a first modification. As illustrated in FIG. 12, this modification does not need baffles 4 for all of the protrusions 3. In the example of FIG. 12, no baffles 4 are arranged for protrusions 3 located within the first protrusion rows L1, and L3, and the third-closest protrusion row L to the inlet 101H. Baffles 4 are arranged for protrusions 3 located within the remaining protrusion rows L.

As described, this modification does not need baffles 4 for the respective protrusions 3. That is, baffles 4 are arranged for a subset of the protrusions 3. Stated differently, the baffles 4 are arranged for the respective protrusions 3.

At least one baffle 4 may be disposed on the third surface 103. In this case, the at least one baffle 4 may be disposed for the at least one protrusion 3 and enhances the cooling performance of the cooler 100.

### 2-2. Second Modification

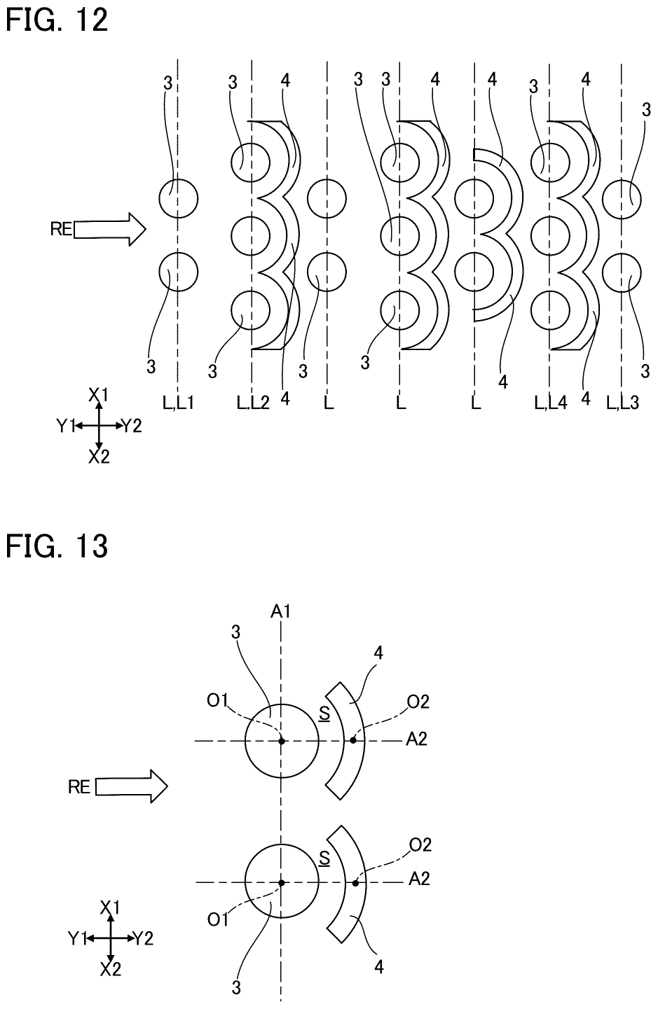

FIG. 13 is a plan view of baffles 4 according to a second modification. In the second modification, as illustrated in FIG. 13, baffles 4 for a subset of the protrusions 3 located with the same protrusion row L are not connected to each other, but are instead spaced apart. That is, the protrusions 3 include two or more protrusions 3 that are arranged and spaced apart from each other along the X1 direction, which is orthogonal to the direction of flow of the refrigerant RE. Two or more baffles 4 are arranged for the respective two or more protrusions 3. The two or more baffles 4 are spaced apart from each other.

The arrangement of these baffles 4 at intervals within the same protrusion row L effectively prevents a reduction in the flow rate and flow velocity of the refrigerant RE within region S, as compared to when the baffles 4 are interconnected. Furthermore, the baffles 4 prevent an increase in pressure loss, thereby maintaining a higher overall flow rate.

### 2-3. Third Modification

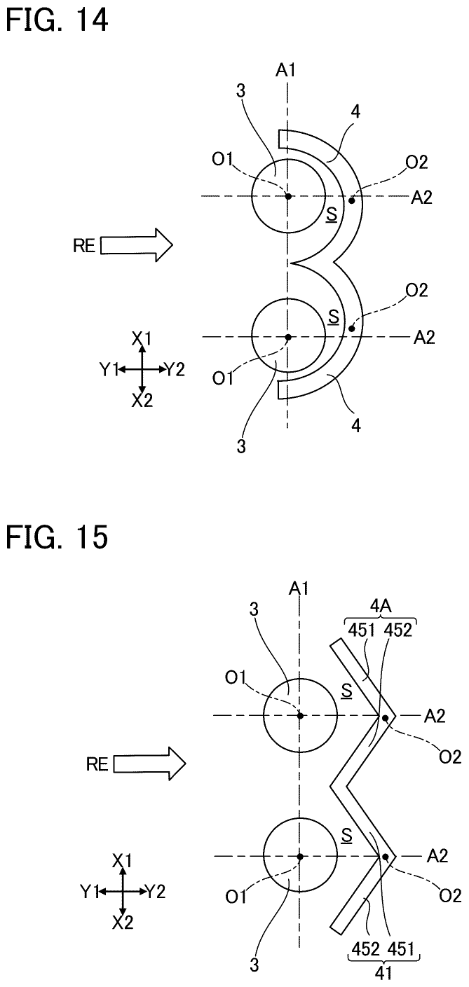

FIG. 14 is a plan view of baffles 4 according to a third modification. In the third modification illustrated in FIG. 14, each baffle 4 is not concentric with a corresponding protrusion 3. A distance between the baffle 4 and the protrusion 3 varies over the entire region of the baffle 4. A line segment A2, which extends through the center O1 of the protrusion 3 in the direction of flow of refrigerant RE, does not intersect the center O2 of baffle 4.

Thus, each baffle 4 may be offset relative to the corresponding protrusion 3. For example, the placement of each baffle 4 may be offset relative to the protrusion 3 depending on the distance to the side wall 15.

Similarly, the offset may be determined based on imbalances in the flow rate and flow velocity of the refrigerant RE.

### 2-4. Fourth Modification

FIG. 15 illustrates baffles 4A according to a fourth modification. Each baffle 4A, according to the fourth modification illustrated in FIG. 15, includes a straight portion rather than an arc-shaped portion in plan view. Specifically, each baffle 4A includes a first baffle 451 and a second baffle 452. The first baffle 451 extends linearly from the center O2 and is oriented toward an upper-left direction on the paper surface (a direction of intersection of the X and Y axes). The second baffle 452 also extends linearly from the center O2 but is oriented toward a lower-left direction (the direction of intersection of the X and Y axes). The portion of baffle 4A through which line segment A2 passes is located closest to outlet 102H. The baffles 4A for the respective protrusions 3 located within the same protrusion row L are connected to each other, although they may be spaced apart.

Such baffles 4A prevent decreases in flow rates and flow velocities in the region S.

### 2-5. Fifth Modification

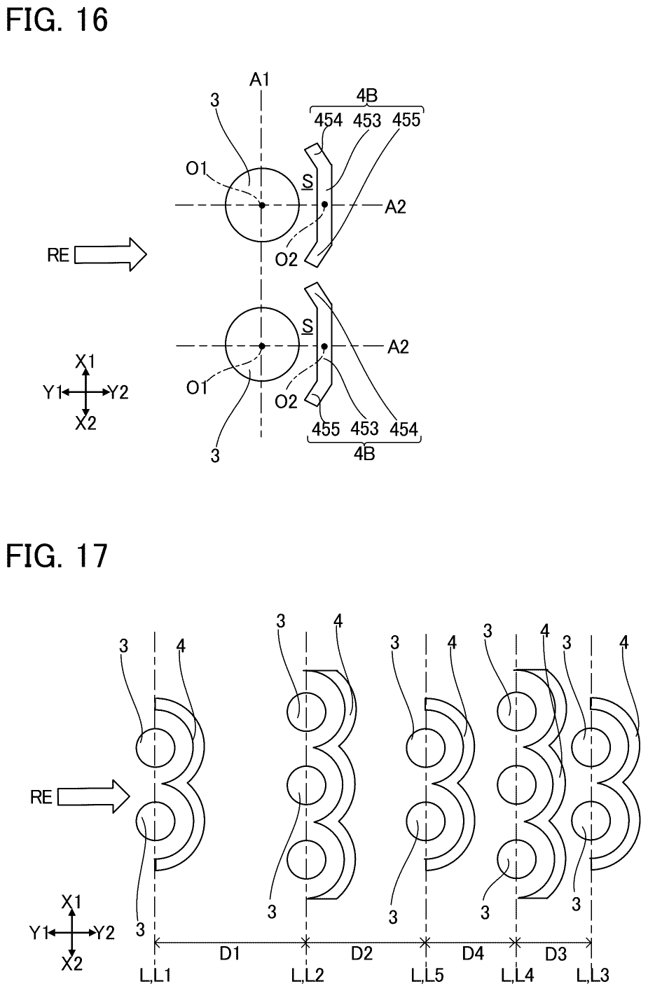

FIG. 16 illustrates baffles 4B according to a fifth modification. Each baffle 4B, according to the fifth modification illustrated in FIG. 16, includes a straight portion rather than an arc-shaped portion in plan view. Specifically, each baffle 4B includes a third baffle 453, a fourth baffle 454, and a fifth baffle 455. The third baffle 453 passes through a line segment A2, and extends linearly in the X1 direction, which is orthogonal to the direction of flow of the refrigerant RE. The fourth baffle 454 extends linearly from a first end of the third baffle 453 and is oriented toward the upper-left direction on the paper surface (the direction of intersection of the X and Y axes). The fifth baffle 455 also extends linearly from a second end of the third baffle 453 but is oriented toward the lower-left direction (the direction of intersection of the X and Y axes). Baffles 4B, corresponding to protrusions 3 located within the same protrusion row L, are connected to each other, though they may be spaced apart.

These baffles 4B serve to prevent decreases in flow rate and flow velocity in the region S.

### 2-6. Sixth Modification

FIG. 17 illustrates protrusions 3 and baffles 4 according to a sixth modification. In the sixth modification illustrated in FIG. 17, distances between two adjacent protrusion rows L are not uniform. Specifically, a distance D1 between the first protrusion row L1 and the second protrusion row L2 is greater than a distance D3 between the third protrusion row L3 and the fourth protrusion row L4. Furthermore, a protrusion row L between the second protrusion row L2 and the third protrusion row L3 is defined as a fifth protrusion row L5. In this case, distances decrease in order from the distance D1: a distance D2 between the second protrusion row L2 and the fifth protrusion row L5, a distance D4 between the fifth protrusion row L5 and the third protrusion row L3, and finally, the distance D3. That is, the distances D1, D2, D4, and D3 satisfy the relationship D1>D2>D4>D3. Thus, the distances between two adjacent protrusion rows L gradually decrease from the inlet 101H toward the outlet 102H.

Additionally, since the distances between adjacent protrusion rows L gradually decrease from the inlet 101H toward the outlet 102H, the flow velocity of the refrigerant RE correspondingly increases along the same direction. This configuration effectively reduces uneven cooling performance on the first surface 201 of the second member 1. However, adjacent protrusion rows may be spaced apart at the same intervals.

### 2-7. Seventh Modification

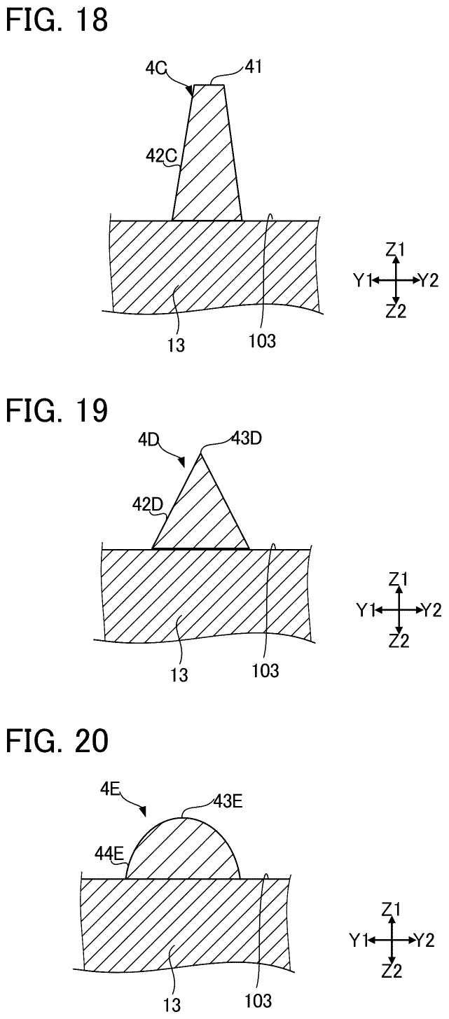

FIG. 18 illustrates a baffle 4C according to a seventh modification. In the seventh modification illustrated in FIG. 18, a side surface 42C of the baffle 4C is non-parallel to the Z axis. The baffle 4C is trapezoidal in cross-section. The baffle 4C has a width that decreases as being farther away from the third surface 103.

### 2-8. Eighth Modification

FIG. 19 illustrates a baffle 4D according to an eighth modification. In the eighth modification illustrated in FIG. 19, the baffle 4D has a vertex 43D and a side surface 42D. The side surface 42D is non-parallel to the Z axis. The baffle 4D is triangular in cross-section and has a width that decreases as it extends away from the third surface 103. The width tapers to zero at the vertex 43D.

### 2-9. Ninth Modification

FIG. 20 illustrates a baffle 4E according to a ninth modification. In the ninth modification illustrated in FIG. 20, the baffle 4E has a vertex 43E and an outer surface 44E. The outer surface 44E has a hemispherical shape. The baffle 4E is semicircular in cross-section.

### 2-10. Tenth Modification

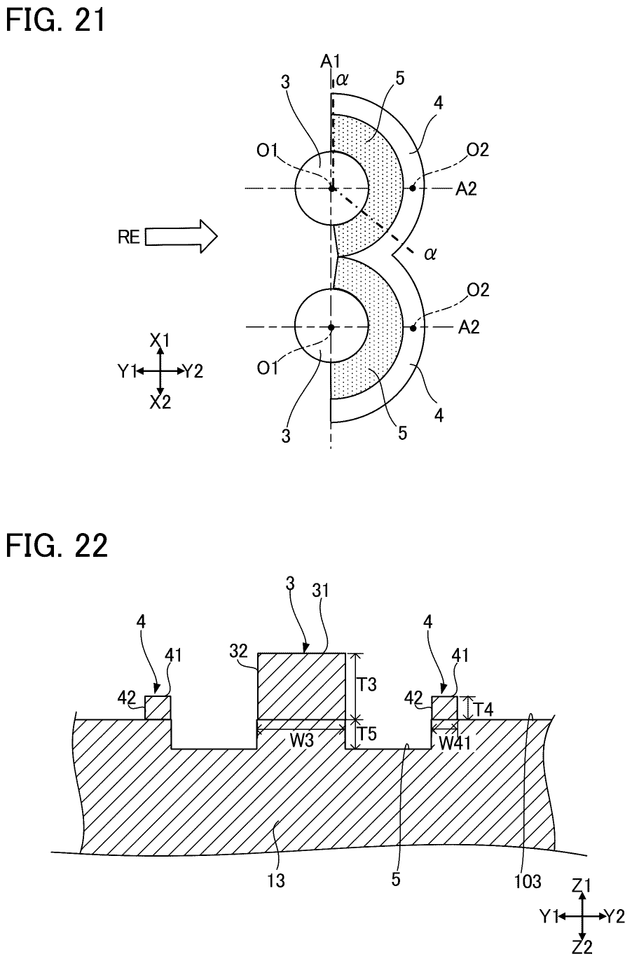

FIG. 21 illustrates a portion of the second member 1 according to a tenth modification. FIG. 22 is a cross-sectional view taken along line α-α of FIG. 21.

As illustrated in FIGS. 21 and 22, the third surface 103 of the second member 1 has a groove 5, which is indicated by dotted markings in FIG. 21 for clarity. The groove 5 is a recess located between the protrusion 3 and the baffle 4. The groove 5 is formed on the third surface 103 and is positioned on the side of protrusion 3 opposite the inlet 101H and is located closer to the outlet 102H than the virtual line A1.

The groove 5 allows the refrigerant RE, which flows alongside protrusion 3, to enter and travel along the grooves. This configuration increases the flow rate of the refrigerant RE in region S, which is located between the protrusion 3 and the baffle 4, as compared to a configuration without the grooves 5. As a result, such a groove 5 enhances the cooling performance of the cooler 100.

In this modification, the groove 5 is quadrangular in cross-section and has a bottom surface and a side surface. The bottom surface is farthest from the third surface 103 and is parallel to the X-Y plane, similarly to the third surface 103. The side surface connects the third surface 103 to the bottom and is a surface parallel to the Z axis. The bottom and side surfaces are flat.

A depth T5 of the groove 5 is not particularly limited; however, it is equal to the protruding height T4 and less than the protruding height T3. Setting the depth T5 effectively prevents a deceleration of flow of the refrigerant RE in the region S.

The depth T5 may be less than the protruding height T4, or it may be greater than the protruding height T4. The depth T5 may be the protruding height T3 or less.

Furthermore, the grooves 5 extend across the entire region S. As a result, as compared to when a groove 5 is provided only in part of the region S, the flow of the refrigerant RE is more effectively maintained without deceleration in this region S.

### 2-11. Eleventh Modification

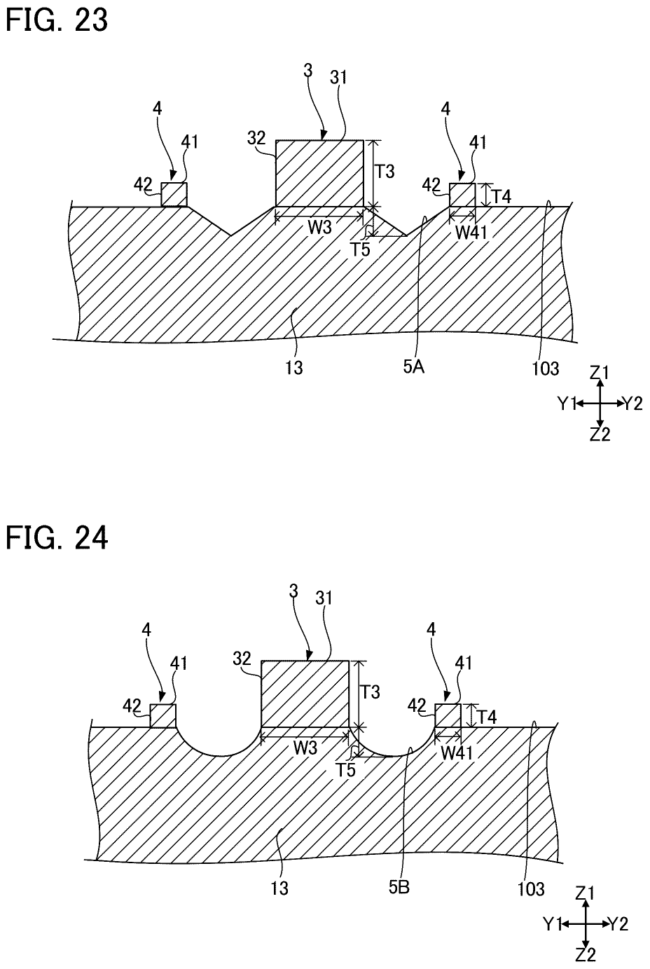

FIG. 23 is a cross-sectional view of a portion of the second member 1 according to an eleventh modification. The differences from the tenth modification will be primarily described below.

As illustrated in FIG. 23, a groove 5A, according to the eleventh modification, is triangular in cross-section. The groove 5A has a non-uniform depth T5. The depth T5 reaches a maximum along its centerline, which lies equidistant from the protrusion 3 and the baffle 4 in plan view. The side surface is gradually inclined relative to the Z axis such that the depth T5 increases toward the center line.

Similarly to the tenth modification, such a groove 5A serves to prevent a deceleration of flow of the refrigerant RE in the region S, as compared to when no groove 5A is provided.

### 2-12. Twelfth Modification

FIG. 24 is a cross-sectional view of a portion of the second member 1 according to a twelfth modification. The differences from the eleventh modification will be primarily described below.

As illustrated in FIG. 24, a groove 5B, according to the twelfth modification, has a curved surface. Accordingly, the groove 5B is not necessarily flat. It may be curved, stepped, or irregular.

Such a groove 5B serves to prevent a deceleration of flow of the refrigerant RE in the region S, as compared to when no groove 5B is provided.

### 2-13. Thirteenth Modification

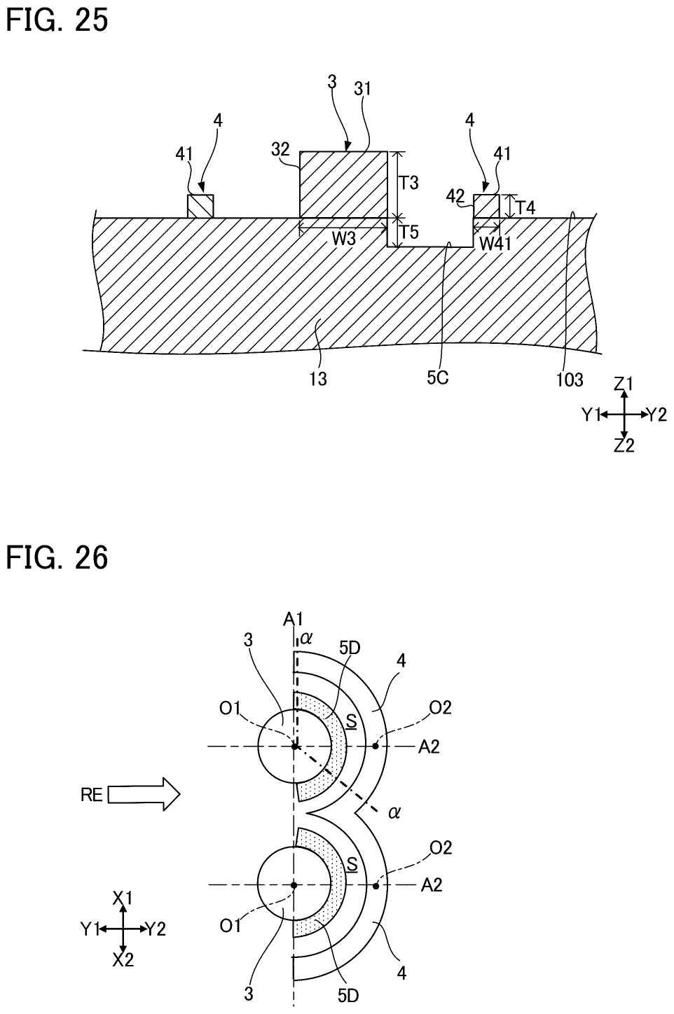

FIG. 25 is a cross-sectional view of a portion of the second member 1 according to a thirteenth modification. The differences from the tenth modification will be primarily described below.

As illustrated in FIG. 25, a groove 5C has a non-uniform depth T5 across its length. In this modification, the depth T5 gradually increases from the inlet 101H toward the outlet 102H. In FIG. 25, the inlet 101H is located on the left, and the outlet 102H is located on the right.

Since the depth T5 increases from the inlet 101H toward the outlet 102H, the refrigerant RE flows smoothly along the shape, thereby increasing the flow rate of the refrigerant RE flowing into the region S without causing a pressure loss due to flow separation.

### 2-14. Fourteenth Modification

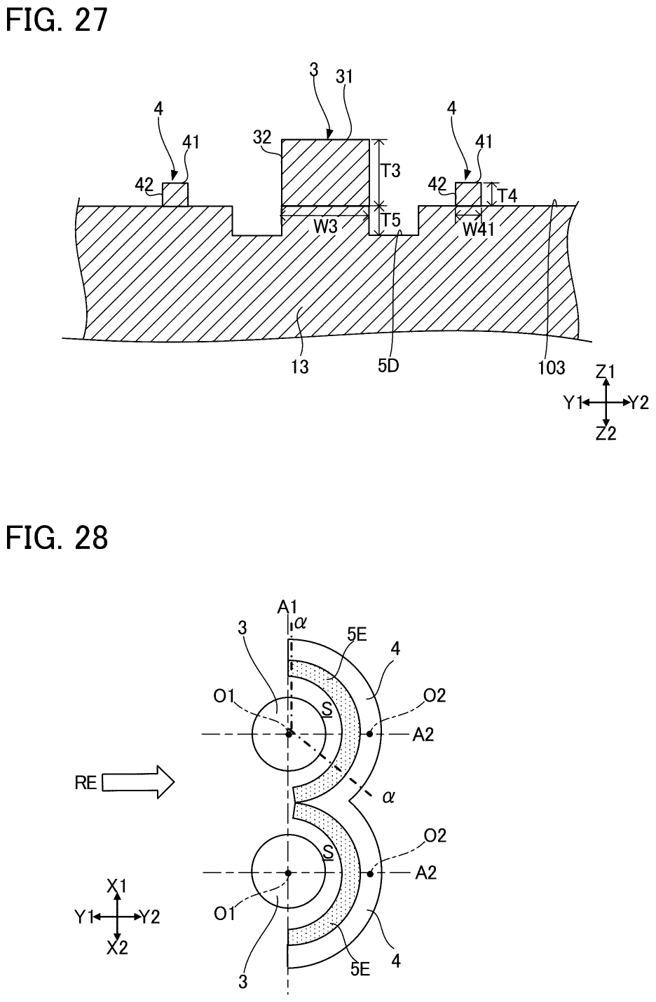

FIG. 26 illustrates a portion of the second member 1 according to a fourteenth modification. FIG. 27 is a cross-sectional view taken along line α-α of FIG. 26. The differences from the tenth modification will be primarily described below.

As illustrated in FIGS. 26 and 27, in this modification, a groove 5D is not provided across the entire region S. Instead, a groove 5D is provided in a portion of the region S. Specifically, the groove 5D is located on a side of the region S adjacent to the protrusion 3. A side portion of the groove 5D is flush with and continuous with a part of the side surface 32 of the protrusion 3.

Such a groove 5D serves to prevent a deceleration of flow of the refrigerant RE in the region S, as compared to when no groove 5D is provided.

### 2-15. Fifteenth Modification

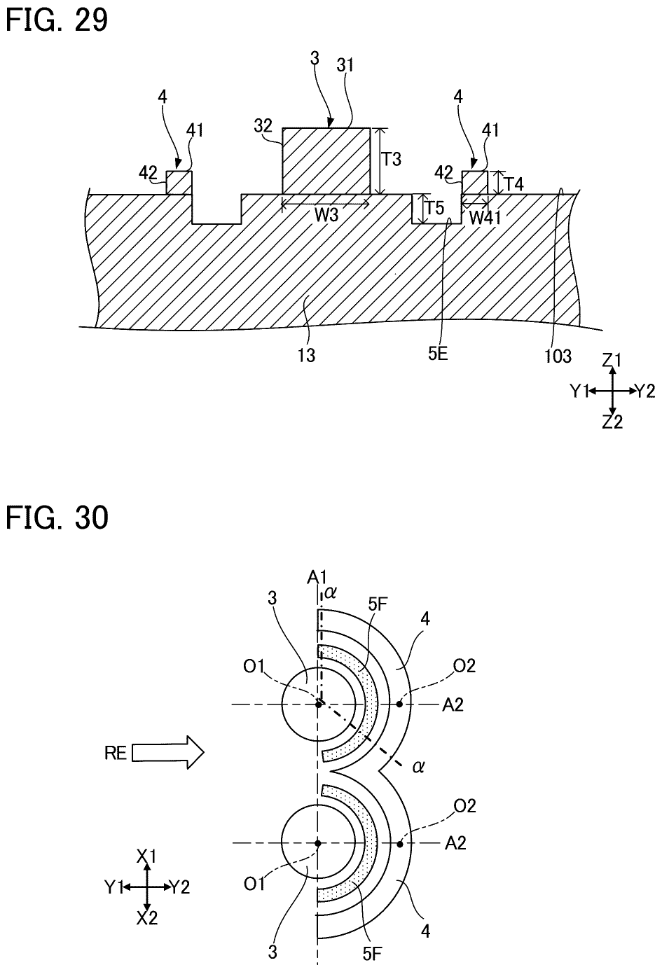

FIG. 28 illustrates a portion of the second member 1 according to a fifteenth modification. FIG. 29 is a cross-sectional view taken along line α-α of FIG. 28. The differences from the fourteenth modification will be primarily described below.

As illustrated in FIGS. 28 and 29, in this modification, a groove 5E is located close to the baffle 4 in the region S. A side portion of the groove 5E is flush with, and is continuous with, a part of the side surface 42 of the baffle 4.

Such a groove 5E serves to prevent a deceleration of flow of the refrigerant RE in the region S, as compared to when no groove 5E is provided.

### 2-16. Sixteenth Modification

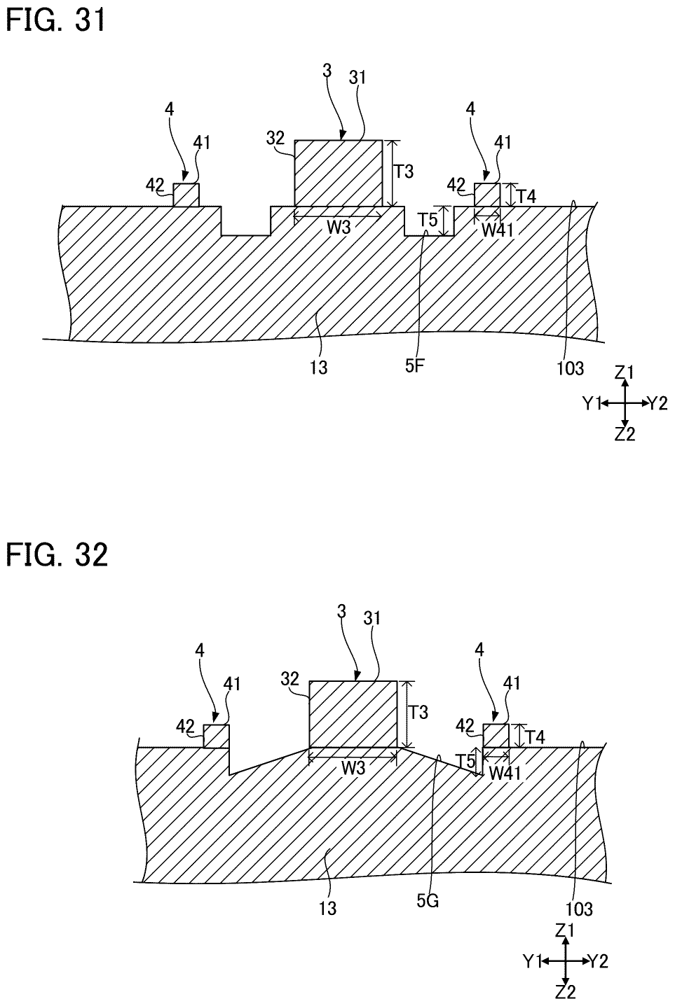

FIG. 30 illustrates a portion of the second member 1 according to a sixteenth modification. FIG. 31 is a cross-sectional view taken along line α-α of FIG. 30. The differences from the fourteenth modification will be primarily described below.

As illustrated in FIGS. 30 and 31, in this modification, a groove 5F is spaced apart from the baffle 4 and the protrusion 3 at substantially equal intervals in plan view. The groove 5F is located along the center line of the region S in plan view.

Such a groove 5F serves to prevent deceleration of flow of the refrigerant RE in the region S, as compared to when no groove 5F is provided.

### 2-17. Seventeenth Modification

FIG. 32 is a cross-sectional view of a portion of the second member 1 according to a seventeenth modification. The differences from the tenth modification will be primarily described below.

As illustrated in FIG. 32, in this modification, a groove 5G has a non-uniform depth T5 across the entire region S and varies from the protrusion 3 toward the baffle 4. Specifically, the depth T5 gradually decreases from the protrusion 3 toward the baffle 4. Such a groove 5G serves to prevent a deceleration of flow of the refrigerant RE in the region S.

The groove 5G is triangular in cross-section. The depth T5 does not need to gradually vary from the protrusion 3 toward the baffle 4. Instead, the depth T5 may vary in a stepwise manner. In this example, although the groove 5G extends across the entire region S, it may extend in only a portion of the region S. For example, the groove 5G may be partially located as in the fourteenth, fifteenth, and sixteenth modifications.

### 2-18. Eighteenth Modification

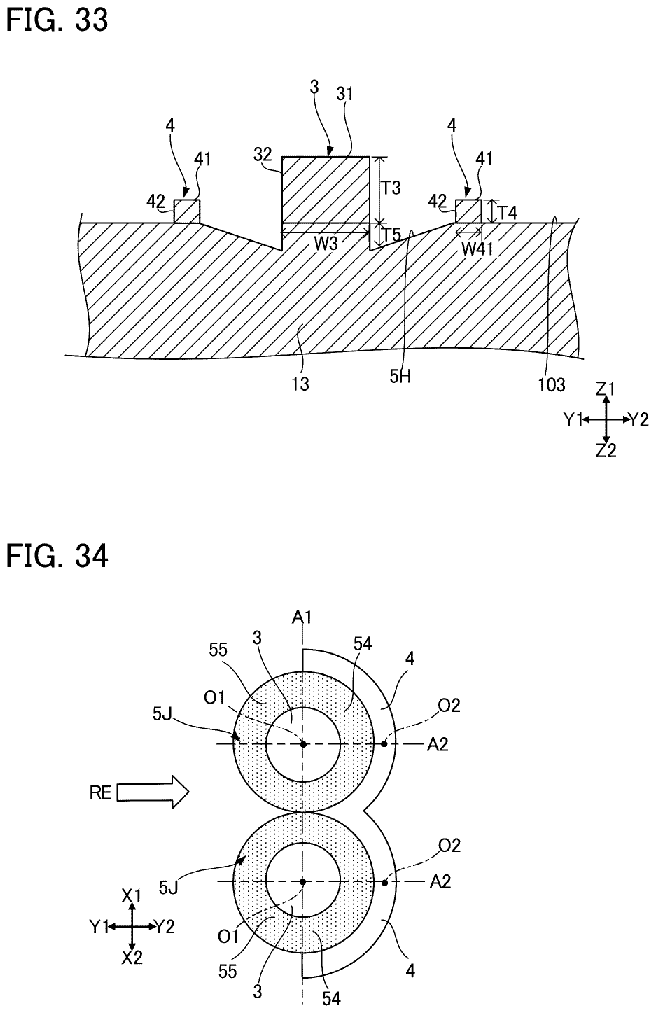

FIG. 33 illustrates a portion of the second member 1 according to an eighteenth modification. The differences from the seventeenth modification will be primarily described below.

As illustrated in FIG. 33, in this modification, a groove 5H has a depth T5 that gradually decreases from the baffle 4 toward the protrusion 3. Such a groove 5H serves to prevent a deceleration of flow of the refrigerant RE in the region S.

The groove 5H is triangular in cross-section. The depth T5 does not need to gradually vary from the baffle 4 toward the protrusion 3. Instead, the depth T5 may vary in a stepwise manner. In this example, although the groove 5H extends across the entire region S, it may extend in only a portion of the region S, as in the fourteenth, fifteenth, and sixteenth modifications.

### 2-19. Nineteenth Modification

FIG. 34 illustrates a portion of the second member 1 according to a nineteenth modification. FIG. 35 is a cross-sectional view taken along line segment A2 of FIG. 34. The differences from the tenth modification will be primarily described below.

As illustrated in FIGS. 34 and 35, in this modification, a groove 5J is provided not only on a side close to the outlet 102H but also on a side close to the inlet 101H, with respect to the protrusion 3. That is, the groove 5J surrounds the protrusion 3 in plan view.

The groove 5J includes an outlet groove 54 and an inlet groove 55. The inlet groove 55 is located on the side close to the inlet 101H of the protrusion 3 and is closer to the inlet 101H than the virtual line A1. The outlet groove 54 is located on the side close to the outlet 102H of the protrusion 3 and is closer to the outlet 102H than the virtual line A1.

In this modification, a depth T5 of the outlet groove 54 equals to a depth T5 of the inlet groove 55 but they may differ. The outlet groove 54 and the inlet groove 55 both are quadrangular in cross-section, although their shapes may differ.

Such a groove 5J serves to prevent a deceleration of flow of the refrigerant RE in the region S. Furthermore, forming a groove 5J to surround the protrusion 3 reduces stagnation of a refrigerant RE in the region S, as compared to when the groove 5J does not enclose the protrusion 3.

### 2-20. Twentieth Modification

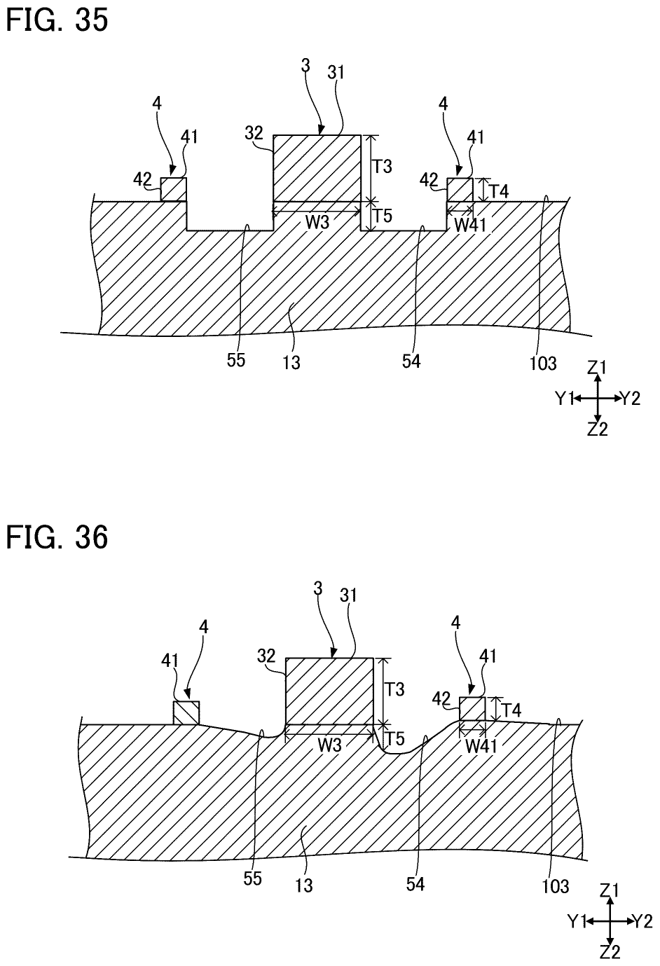

FIG. 36 illustrates a portion of the second member 1 according to a twentieth modification. The differences from the nineteenth modification will be primarily described below.

As illustrated in FIG. 36, in this modification, the cross-sectional shape and depth are not uniform. In the example of FIG. 36, the outlet groove 54 and the inlet groove 55 differ in the cross-sectional shape and depth T5. Both the outlet groove 54 and the inlet groove 55 have curved surfaces. The maximum depth of the outlet groove 54 is greater than that of the inlet groove 55. Each of the outlet groove 54 and the inlet groove 55 is deeper on a side close to the protrusion 3 than on a side close to the baffle 4.

The cross-sectional shapes of the outlet side groove 54 and the inlet side groove 55 are not limited to those in the example of FIG. 36.

Both the outlet groove 54 and the inlet groove 55 with curved surfaces reduce a stagnation of the refrigerant RE in the region S, as compared to when these grooves have flat surfaces.

### 2-21. Twenty-First Modification

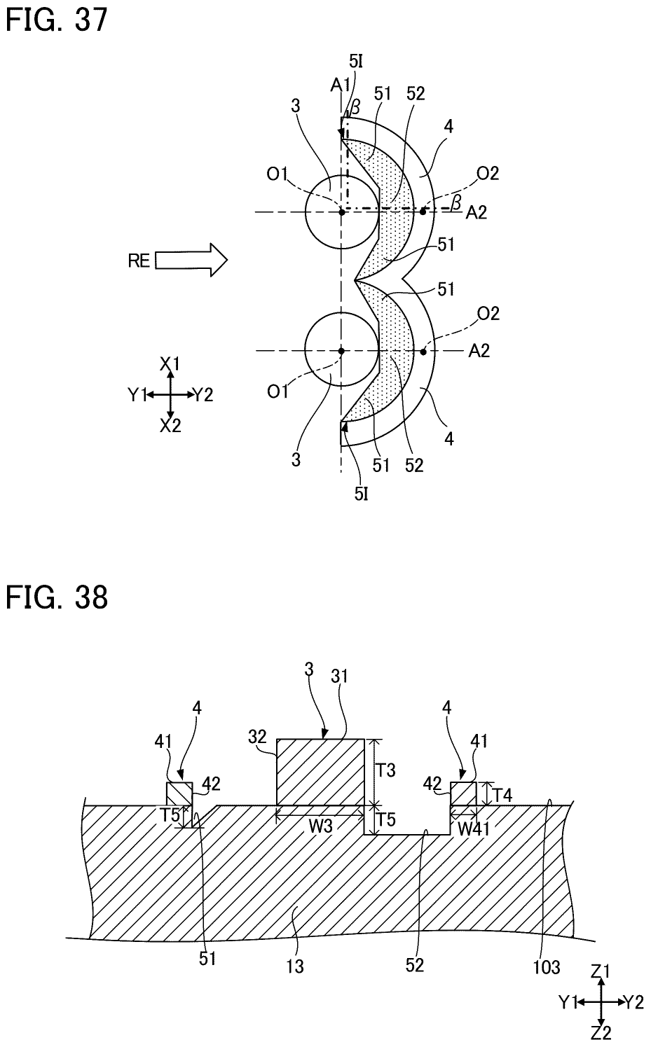

FIG. 37 illustrates a portion of the second member 1 according to a twenty-first modification. FIG. 38 is a cross-sectional view taken along line β-β of FIG. 37. The differences from the tenth modification will be primarily described below.

As illustrated in FIGS. 37 and 38, a groove 5I has groove portions with varying shapes and depths. Specifically, the depth T5 and cross-sectional shape of the groove 5I differ between the region close to the inlet 101H and the region close to the outlet 102H.

More specifically, the groove 5I includes two first groove portions 51 and one second groove portion 52. In plan view, the second groove portion 52 is positioned between the two first groove portions 51, and all three groove portions are connected to them. Among the two first groove portions 51, the one closer to the outlet 102H is adjacent to the second groove portion 52.

The first groove portion 51 is triangular in cross-section. The second groove portion 52 is quadrangle in cross-sectional. The second groove portion 52 has a bottom parallel to the X-Y plane and a side surface parallel to the Z axis. A depth T5 of the first groove portion 51 is less than that of the second groove portion 52. Furthermore, the depth T5 of the first groove portion 51 increases toward the second groove portion 52. Alternatively, the depth T5 of the first groove portion 51 may be equal to that of the second groove portion 52.

The groove 5I serves to prevent a deceleration of flow of the refrigerant RE in the region S. Furthermore, designing the depth T5 to gradually increase from the inlet 101H to the outlet 102H reduces stagnation of a refrigerant RE in the region S, as compared to when the depth T5 does not increase from the inlet 101H toward the outlet 102H.

### 2-22. Twenty-Second Modification

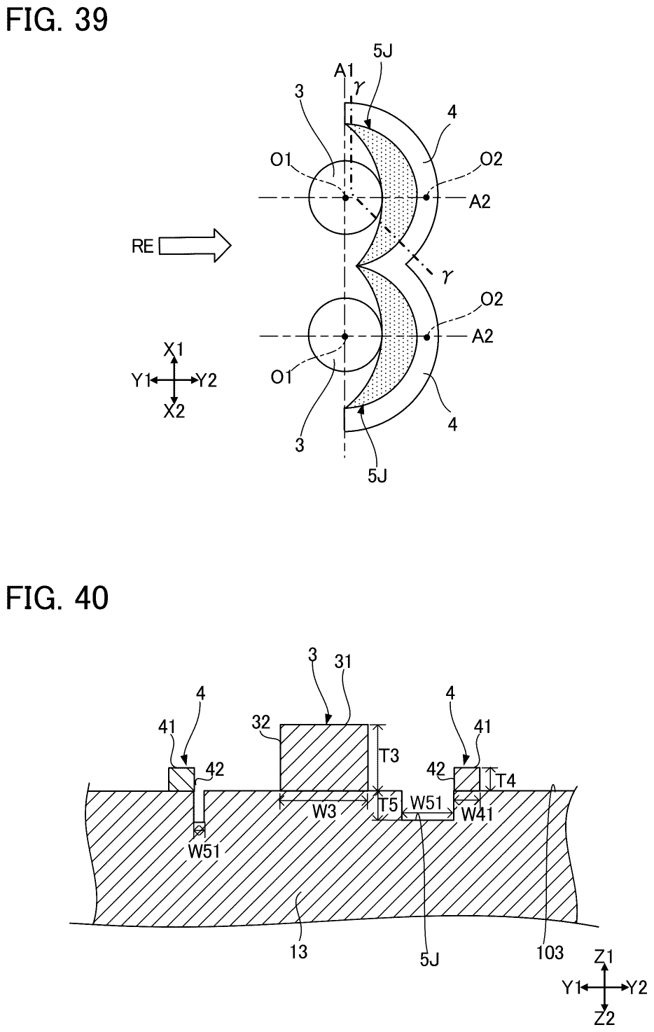

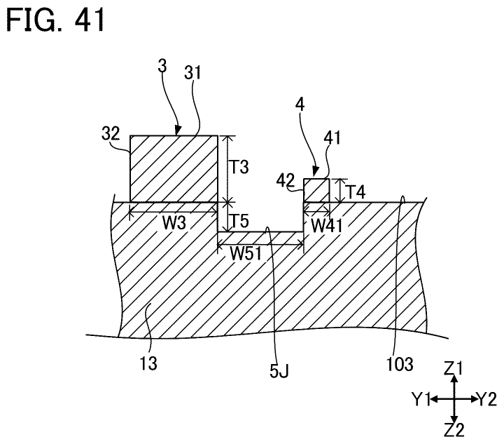

FIG. 39 illustrates a portion of the second member 1 according to a twenty-second modification. FIG. 40 is a cross-sectional view taken along line γ-γ of FIG. 39. FIG. 41 is a cross-sectional view taken along line segment A2 of FIG. 39. The differences from the twenty-first modification modification will be primarily described below.

As illustrated in FIGS. 39, 40, and 41, a groove 5J is mainly located within a specific area of the region S, that is, a side adjacent to the baffle 4. The groove 5J has a width W51 that is not uniform. Specifically, the width W51 gradually increases from the inlet 101H toward the outlet 102H. The width W51 is a length of the groove 5J along a radial direction from the center O1. In this modification, the depth T5 is uniform. However, it may alternatively be varied.

Such a groove 5J serves to prevent deceleration of flow of the refrigerant RE in the region S. In addition, increasing the width W51 from the inlet 101H toward the outlet 102H reduces the refrigerant RE stagnation in the region S, as compared to a configuration with constant width.

### 2-23. Other Modifications

The shapes of the baffles 4 are not limited thereto, as in the first embodiment and the seventh, eighth, and ninth modifications. For example, the side surface 42 of each baffle 4 may have an inclination angle, relative to the Z axis, that varies between the region close to the inlet 101H and the region close to the outlet 102H. The top surface 41 may be non-parallel to the third surface 103. All the baffles 4 may differ in shape and protruding height.

The shapes of the protrusions 3 are not limited thereto as in the first embodiment. For example, the protrusions 3 may have shapes similar to those of the baffles 4, as seen in the seventh, eighth, and ninth modifications. For example, the side surface 32 of each protrusion 3 may have an inclination angle, relative to the Z axis of the side surface 42, that differs between the region close to the inlet 101H and the region close to the outlet 102H. The top surface 31 may be non-parallel to the third surface 103. All the protrusions 3 may differ in shape and protruding height.

Although this disclosure has been described with reference to the illustrated embodiment, it is not limited thereto. Each element of this disclosure may be substituted with any configuration that performs a function similar to that described in the foregoing embodiment, and additional configurations may also be incorporated.

### 3. Supplemental Notes

The following aspects can be derived from the foregoing embodiments or modifications.

A cooler according to Aspect 1 of this disclosure includes a case including: an inlet for a refrigerant; an outlet for the refrigerant; a first member with a first surface that absorbs heat from a cooled body and a second surface opposite to the first surface; a second member with a third surface facing the second surface; a plurality of protrusions that extends from the third surface toward the second surface; and at least one baffle that is disposed for at least one protrusion from among the plurality of protrusions and extends from the third surface toward the second surface. The at least one baffle has a protruding height that is less than a protruding height of the at least one protrusion. The at least one baffle is spaced apart from the at least one protrusion and is disposed on a side opposite the inlet relative to the at least one protrusion.

According to Aspect 1, the baffle serves to prevent deceleration of flow of the refrigerant in the downstream region of the protrusions (the region toward the outlet). Aa result, the thermal resistance on the third surface is reduced across the entire region, thereby enhancing the cooling performance of the cooler.

In Aspect 2 according to Aspect 1, the at least one baffle is disposed closer to the outlet than a virtual line. The virtual line passes through a center of the at least one protrusion along a second direction orthogonal to a first direction of flow of the refrigerant in plan view.

Such a cooler effectively serves to prevent a decrease in flow velocity and flow rate of the refrigerant in the downstream region of the baffle (the region toward the outlet).

In Aspect 3 according to Aspect 2, the plurality of protrusions comprises two or more protrusions arranged apart from each other in the second direction. The at least one baffle comprises two or more baffles, each corresponding to a respective one of the two or more protrusions. The two or more baffles are connected to each other.

Connecting the baffles to each other serves to prevent decreases in the flow velocity and flow rate of refrigerant in the region, as compared to when the baffles are not connected.

In Aspect 4 according to Aspect 2, the plurality of protrusions comprises two or more protrusions arranged apart from each other in the second direction. The at least one baffle comprises two or more baffles, each corresponding to a respective one of the two or more protrusions. The two or more baffles are spaced apart from each other.

The arrangement of these baffles at intervals prevents a reduction in flow velocity and flow rate of the refrigerant in the downstream region of the protrusions (the region toward the outlet), as compared to when no baffles are connected to each other. Furthermore, the baffles serve to prevent an increase in pressure loss, thereby maintaining a higher overall flow rate.

In Aspect 5 according to any one of Aspects 1 to 4, the at least one protrusion is circular in plan view. The at least one baffle has an arc shape corresponding to the at least one protrusion in plan view.

The arc-shaped baffle increases the flow rate and flow velocity of the refrigerant in the downstream region of the baffle (the region toward the outlet) without requiring an offset, as compared to with a straight baffle.

In Aspect 6 according to Aspect 1, the at least one baffle is concentric with the at least one protrusion.

The baffle concentric with the protrusion increases the flow rate and flow velocity of the refrigerant in the downstream region of the baffle (the region toward the outlet) without requiring an offset.

In Aspect 7 according to any one of Aspects 1 to 6, the at least one baffle comprises a plurality of baffles, each corresponding to a respective one of the plurality of protrusions.

These baffles serve to prevent decreases in flow velocity and flow rate of the refrigerant in the downstream region of all the protrusions (the region toward the outlet), which effectively improves the cooling performance of the cooler.

In Aspect 8 according to any one of Aspects 1 to 7, the plurality of protrusions is grouped into two or more protrusion rows arranged at intervals along a first direction of flow of the refrigerant. The two or more protrusion rows includes: a first protrusion row closest to the inlet; a second protrusion row next closest to the inlet after the first protrusion row; a third protrusion row closest to the outlet; and a fourth protrusion row next closest to the outlet after the third protrusion row. A distance between the first protrusion row and the second protrusion row is greater than a distance between the third protrusion row and the fourth protrusion row.

The arrangement of the protrusions increases the flow velocity of the refrigerant in the vicinity of the outlet and reduces increase in temperature of the refrigerant in the vicinity of the outlet. As a result, uneven cooling on the first surface of the second member can be reduced.

In Aspect 9 according to any one of Aspects 1 to 8, the third surface has a groove located between the at least one baffle and the at least one protrusion.

The groove serves to effectively prevent a deceleration of flow of the refrigerant between the baffle and the protrusion.

### Description of References Signs

1 . . . second member, 2 . . . first member, 3 . . . protrusion, 4, 4A, 4B, 4C, 4D, 4E . . . baffle, 9 . . . cooled body, 10 . . . case, 11 . . . bottom, 13 . . . base, 15 . . . side wall, 31 . . . top surface, 32 . . . side surface, 41 . . . top surface, 42, 42C, 42D . . . side surface, 43D, 43E . . . vertex, 44E . . . outer surface, 100 . . . cooler, 101H . . . inlet, 102H . . . outlet, 103 . . . third surface, 151 . . . first side wall, 152 . . . second side wall., 153 . . . third side wall, 154 . . . fourth side wall, 201 . . . first surface, 202 . . . second surface, 451 . . . first baffle, 452 . . . second baffle, 453 . . . third baffle, 454 . . . fourth baffle, 455 . . . fifth baffle, A1 . . . virtual line, A2 . . . line segment, D1, D2, D3, D4 . . . distance, L . . . protrusion row, L1 . . . first protrusion row, L2 . . . second protrusion row, L3 . . . third protrusion row, L4 . . . fourth protrusion row, L5 . . . fifth protrusion row, O1 . . . center, O2 . . . center, RE . . . refrigerant, S, S0, Sx, Sy. region, T1, T2 . . . protruding height, W3, W40, W41 . . . width.

What is claimed is:

1. A cooler comprising:
a case comprising:
an inlet for a refrigerant;
an outlet for the refrigerant;
a first member with a first surface that absorbs heat from a cooled body and a second surface opposite to the first surface;
a second member with a third surface facing the second surface;
a plurality of protrusions that extends from the third surface toward the second surface; and
at least one baffle that is disposed for at least one protrusion from among the plurality of protrusions and extends from the third surface toward the second surface,
wherein the at least one baffle has a protruding height that is less than a protruding height of the at least one protrusion, and
wherein the at least one baffle is spaced apart from the at least one protrusion and is disposed on a side opposite the inlet relative to the at least one protrusion.

2. The cooler according to claim 1,
wherein the at least one baffle is disposed closer to the outlet than a virtual line,
wherein the virtual line passes through a center of the at least one protrusion along a second direction orthogonal to a first direction of flow of the refrigerant in plan view.

3. The cooler according to claim 2,
wherein the plurality of protrusions comprises two or more protrusions arranged apart from each other in the second direction,
wherein the at least one baffle comprises two or more baffles, each corresponding to a respective one of the two or more protrusions, and
wherein the two or more baffles are connected to each other.

4. The cooler according to claim 2,
wherein the plurality of protrusions comprises two or more protrusions arranged apart from each other in the second direction,
wherein the at least one baffle comprises two or more baffles, each corresponding to a respective one of the two or more protrusions, and
wherein the two or more baffles are spaced apart from each other.

5. The cooler according to claim 1,
wherein the at least one protrusion is circular in plan view, and
wherein the at least one baffle has an arc shape corresponding to the at least one protrusion in plan view.

6. The cooler according to claim 5,
wherein the at least one baffle is concentric with the at least one protrusion.

7. The cooler according to claim 1,
wherein the at least one baffle comprises a plurality of baffles, each corresponding to a respective one of the plurality of protrusions.

8. The cooler according to claim 1,
wherein the plurality of protrusions is grouped into two or more protrusion rows arranged at intervals along a first direction of flow of the refrigerant, and
wherein the two or more protrusion rows comprise:
a first protrusion row closest to the inlet;
a second protrusion row next closest to the inlet after the first protrusion row;
a third protrusion row closest to the outlet; and
a fourth protrusion row next closest to the outlet after the third protrusion row,
wherein a distance between the first protrusion row and the second protrusion row is greater than a distance between the third protrusion row and the fourth protrusion row.

9. The cooler according to claim 1,
wherein the third surface has a groove located between the at least one baffle and the at least one protrusion.
